(19) United States
(12) Patent Application Publication
(10) Pub. No.: US 2014/0197914 A1
(43) Pub. Date: Jul. 17, 2014

(54) TRANSFORMER ASSEMBLIES WITH MOVEABLE TERMINAL BLOCKS

(71) Applicant: ASTEC INTERNATIONAL LIMITED, KOWLOON (HK)

(72) Inventors: Alben Parayday Go Chua, Manila (PH); Billy Gebilaguin Arias, Pasig City (PH)

(73) Assignee: ASTEC INTERNATIONAL LIMITED, KOWLOON (HK)

(21) Appl. No.: 13/743,863

(22) Filed: Jan. 17, 2013

(51) Int. Cl. H01F 27/29; H05K 3/30

(52) U.S. Cl. CPC H01F 27/292; H05K 3/30
USPC 336/192; 29/832

(57) ABSTRACT

A transformer assembly includes a first circuit board, a transformer electrically coupled to the first circuit board, and a terminal block moveably connected to the transformer and moveable relative to the transformer in at least a first direction. The terminal block includes a terminal. The transformer includes a magnetic core and a winding having a winding wire extending from the winding. The winding wire is electrically coupled to the terminal of the terminal block. The transformer assembly further includes a second circuit board electrically coupled to the terminal of the terminal block. Example embodiments and related methods of manufacturing a transformer assembly are also disclosed.

### FIELD

The present disclosure relates to transformer assemblies with moveable terminals blocks.

### BACKGROUND

This section provides background information related to the present disclosure which is not necessarily prior art.

Compact transformer assemblies may include a transformer sandwiched between a primary circuit board and a secondary circuit board. The transformer may include one or more primary windings, one or more secondary windings, a nonconductive insulator, and electrical terminals extending outwardly from the nonconductive insulator. The primary and secondary windings are electrically coupled to the terminals. The transformer is electrically and mechanically coupled to the primary circuit board and the secondary circuit board by soldering the terminals to the primary and secondary circuit boards.

### SUMMARY

This section provides a general summary of the disclosure, and is not a comprehensive disclosure of its full scope or all of its features.

According to one aspect of the present disclosure, a transformer assembly includes a first circuit board, a transformer electrically coupled to the first circuit board, and a terminal block moveably connected to the transformer and moveable relative to the transformer in at least a first direction. The terminal block includes a terminal. The transformer includes a magnetic core and a winding having a winding wire extending from the winding. The winding wire is electrically coupled to the terminal of the terminal block. The transformer assembly further includes a second circuit board electrically coupled to the terminal of the terminal block.

According to another aspect of the present disclosure, a method of manufacturing a transformer assembly is disclosed. The method includes electrically coupling a transformer to a first circuit board, electrically coupling a winding wire from the transformer to a terminal block, moveably connecting the terminal block to the transformer, and manually soldering a terminal of the terminal block to a second circuit board.

Further aspects and areas of applicability will become apparent from the description provided herein. It should be understood that various aspects of this disclosure may be implemented individually or in combination with one or more other aspects. It should also be understood that the description and specific examples herein are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 is a front view of a transformer assembly including circuit boards, a transformer and a moveable terminal block according to one example embodiment of the present disclosure.

FIG. 2 is a front isometric view a transformer assembly including a transformer and a moveable terminal block according to another example embodiment.

FIG. 3 is a rear isometric view of the transformer assembly of FIG. 2.

FIG. 4 is an exploded rear isometric view of a transformer assembly including the transformer assembly of FIGS. 2 and 3 and circuit boards.

FIG. 5 is a rear isometric view of the transformer assembly of FIG. 4.

FIG. 6 is rear view of the transformer assembly of FIGS. 4 and 5 installed in a housing having flanges according to another example embodiment.

FIG. 7 is an isometric view of a transformer assembly similar to the transformer assembly of FIGS. 2 and 3, but including a bobbin according to yet another example embodiment.

FIG. 8 is an isometric view of a power supply system including the transformer assembly of FIG. 7 and circuit boards.

Corresponding reference numerals indicate corresponding parts throughout the several views of the drawings.

### DETAILED DESCRIPTION

Example embodiments will now be described more fully with reference to the accompanying drawings.

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

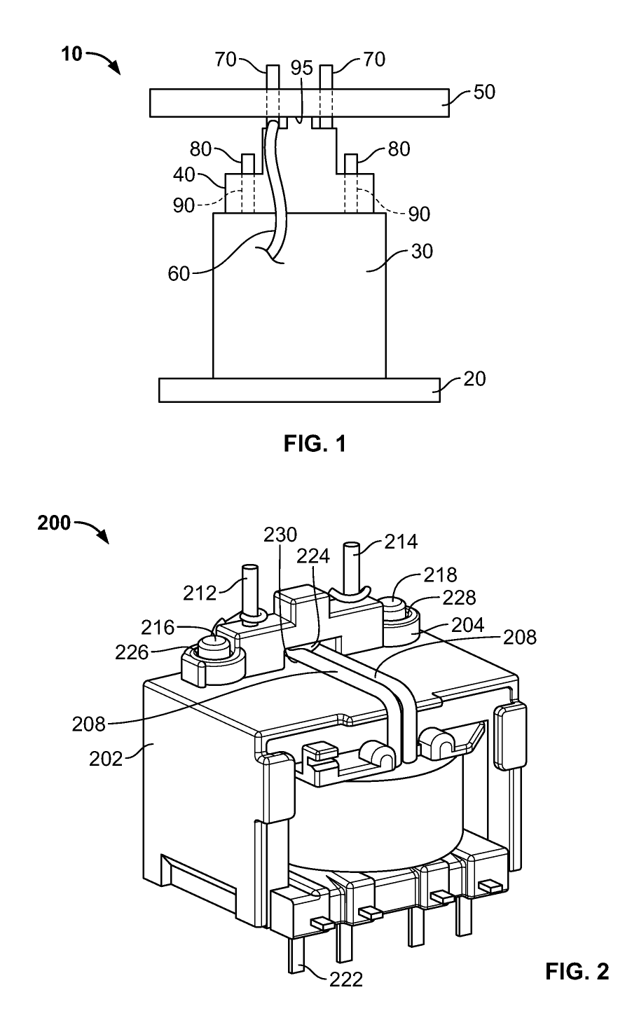

A transformer assembly according to one aspect of the present disclosure is illustrated in FIG. 1 and indicated generally by reference number 10. As shown in FIG. 1, the transformer assembly 10 includes a circuit board 20, a transformer 30 electrically coupled to the circuit board 20, and a terminal block 40 moveably connected to the transformer 30. The terminal block 40 includes terminals 70 extending from the terminal block 40. The assembly 10 further includes a circuit board 50 electrically coupled to the terminals 70 of the terminal block 40.

The transformer 30 includes a magnetic core and a winding having a winding wire 60 extending from the winding. The winding wire 60 is electrically coupled to at least one of the terminals 70 of the terminal block 40. Preferably, the winding wire 60 is a triple-insulated wire.

As shown in FIG. 1, the transformer 30 may further include upwardly extending bosses 80 to moveably connect the terminal block 40 and the transformer 30. In that event, the terminal block 40 may include apertures 90 (shown in phantom in FIG. 1) for receiving the bosses 80. The apertures 90 may be sized for a tight connection with the bosses 80 (i.e., the diameters of the apertures and bosses may be nearly identical). Alternatively, the diameters of the apertures may be somewhat greater than the diameters of the bosses to provide a loose connection that permits the terminal block 40 to be tilted up or down relative to the transformer 30 with the bosses extending through the apertures (i.e., so the circuit boards 20, 50 may not be parallel to one another). It should be understood, however, that the terminal block 40 may be moveably connected to the transformer in another suitable manner (i.e., without using bosses and/or apertures). For example, the terminal block 40 and/or the transformer 30 may include one or more flanges or other structure for moveably connecting the terminal block 40 and the transformer 30.

The terminal block 40 is moveable relative to the transformer 30 in at least one direction. In the example of FIG. 1, the terminal block 40 is moveable relative to the transformer 30 in only the vertical direction along a length of the bosses 80. Therefore, the terminal block 40 may rest on an upper surface of the transformer 30 or, alternatively, the terminal block 40 may be spaced from the upper surface of the transformer 30 so that a gap is formed between the terminal block 40 and the upper surface of the transformer 30. For these reasons, the terminal block 40 may be considered a “floating” terminal block. In some embodiments, the gap may be nearly as large as the length of the bosses 80.

The ability to move the terminal block 40 in the vertical direction allows for adjustments to the distance between the circuit boards 20, 50 and/or to the position of the terminal block 40 (and thus the circuit board 50) relative to the transformer 30. This, in turn, may simply assembly of the transformer assembly 10 and reduce stress on solder joints. Additionally, by employing the terminal block 40, the distance between the circuit boards 20, 50 may be increased, thus increasing the isolation between the circuit boards 20, 50 and components thereon.

Although the example of FIG. 1 illustrates two terminals 70, two bosses 80, and two apertures 90, it should be understood that more or less terminals, bosses and/or apertures may be employed without departing from the scope of the present disclosure.

The winding wire 60 may extend from (or be coupled to) a primary winding, a secondary winding, etc. for coupling the winding to one or more components on the circuit board 50. The terminal block 40 may be moveably connected to any suitable portion of the transformer 30.

As shown in FIG. 1, the terminal block 40 may also include a protrusion 95 for supporting the circuit board 50, and for providing space between the circuit board 50 and the terminal block 40 for electrically coupling winding wire(s) 60 to the terminal 70.

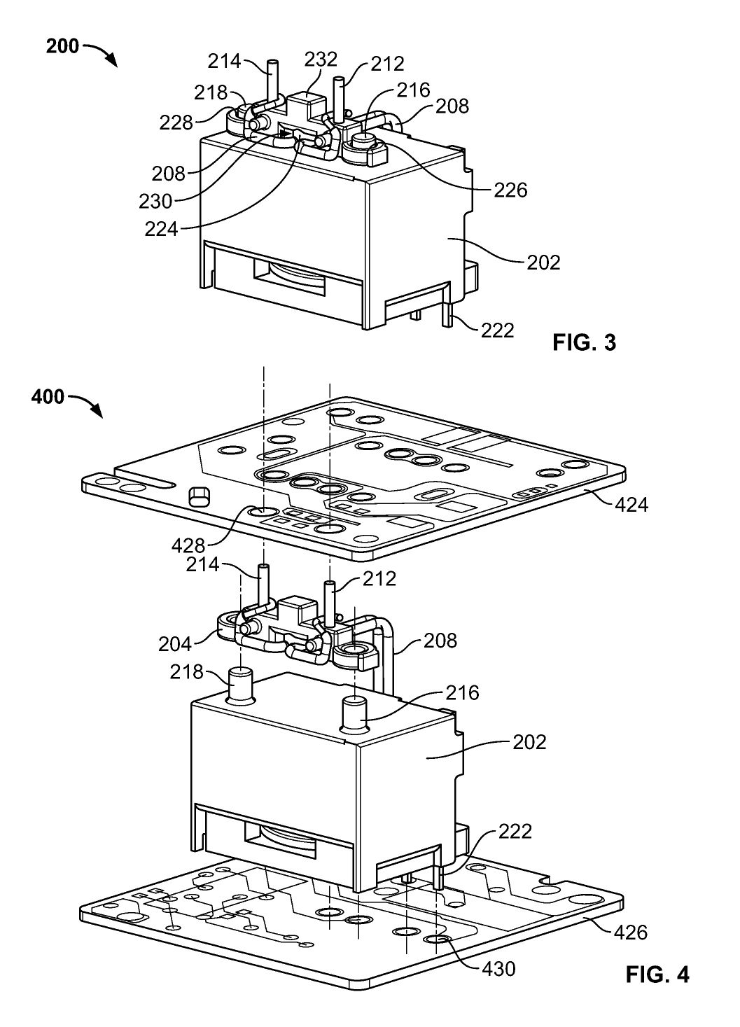

FIGS. 2 and 3 illustrate a transformer assembly 200 according to another example embodiment of the present disclose. The transformer assembly 200 includes a transformer 202 and a terminal block 204 moveably connected to the transformer 202. Although not shown in FIGS. 2 and 3, the transformer 202 includes a magnetic core and windings adjacent the magnetic core.

In the example of FIGS. 2 and 3, the transformer 202 includes two upwardly extending bosses 216, 218. Additionally, the terminal block 204 defines apertures 226, 228 for receiving the bosses 216, 218 to moveably connect the terminal block 204 to the transformer 202.

As shown in FIG. 2, the transformer 202 may include terminals 222 for electrically coupling the transformer 202 to a circuit board. In the example of FIGS. 2 and 3, the terminals 222 are through-hole pins. Alternatively, the terminals 222 may be surface mount terminals or any other suitable terminal for coupling the transformer 202 to a circuit board. Although four terminals 222 are shown FIGS. 2 and 3, more or less terminals may be employed.

Similar to the terminal block 40 of FIG. 1, the terminal block 204 of FIG. 2 is moveable relative to the transformer in a vertical direction along a length of the bosses 216, 218.

The terminal block 204 includes two upwardly extending terminals 212, 214 that can be electrically coupled to one or more circuit boards (not shown). Alternatively, the terminal block 204 may include more or less terminals that extend upwardly or in other directions.

As shown in FIG. 2, the terminal block 204 may define a channel 230. The channel 230 may be positioned adjacent an upper surface of the transformer 202 for routing one or more winding wires 208 through the channel 230 before coupling the winding wires 208 to the terminals 212, 214.

In the particular example shown in FIGS. 2 and 3, secondary winding wires 208 are attached (as indicated by reference number 224) to an upper surface of the channel 230. The winding wires 208 may be attached to the upper surface of the channel 230 in any suitable manner including, for example, via an adhesive (such as epoxy, adhesive tape, etc.), a mechanical clip, etc. Attaching the winding wires 208 to the upper surface of the channel 230 can reduce the likelihood of pinching the winding wires 208 between the terminal block 204 and the transformer 202. Preferably, the winding wires 208 are triple-insulated wires.

As shown in FIG. 3, the terminal block 204 may also include a protrusion 232 for supporting a circuit board, and for providing space between the circuit board and the terminal block 204 for electrically coupling winding wires 208 to the terminals 212, 214.

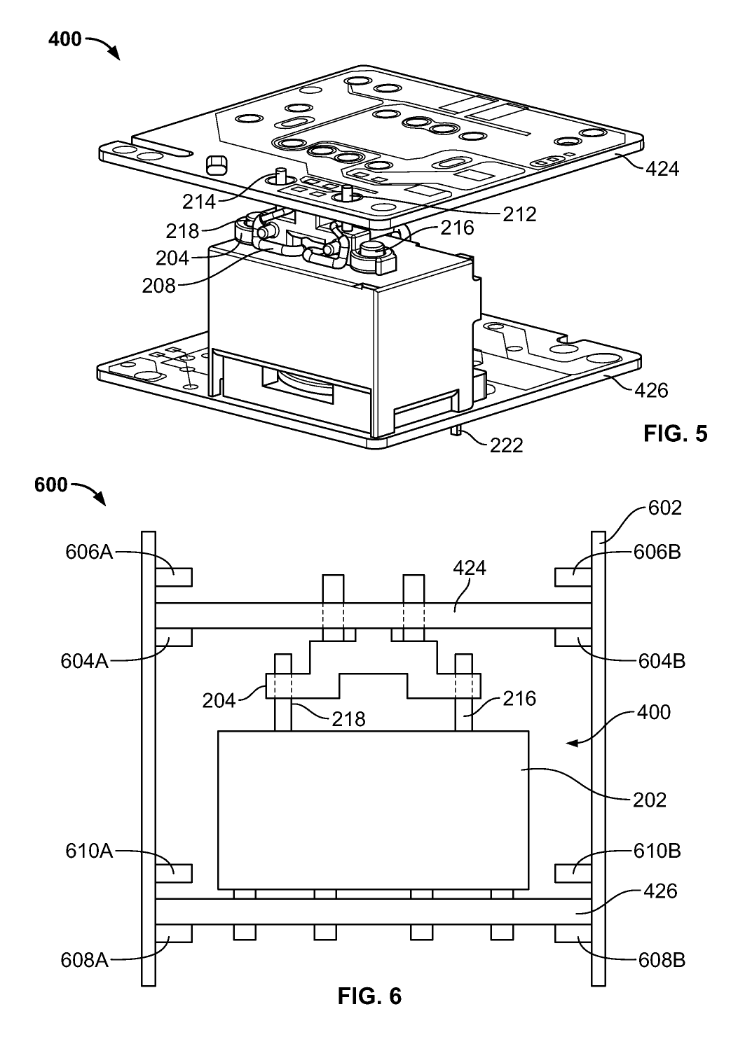

FIGS. 4 and 5 illustrate a transformer assembly 400 that includes the transformer assembly 200 of FIGS. 2 and 3, as well as circuit boards 424, 426. As shown in FIGS. 4 and 5, the circuit boards 424, 426 are positioned on opposing sides of the transformer 202.

In the example of FIG. 4, the circuit board 424 includes plated apertures 428 for receiving the terminals 212, 214 of the terminal block 204. Additionally, the circuit board 426 includes plated apertures 430 for receiving the terminals 222 extending from the transformer 202. Thus, as shown in FIG. 5, the transformer 202 may be electrically and mechanically coupled to the circuit boards 424, 426 by inserting the terminals 212, 214, 222 through the plated apertures 428, 430 and soldering the terminals to the plated apertures (i.e., conductive through-holes). For example, the terminals may be soldered manually and/or by an automated soldering process (e.g., wave soldering, reflow soldering, etc.). Preferably, the terminals 222 are wave soldered to the circuit board 426 while the terminals 212, 214 of the terminal block 204 are manually soldered to the circuit board 424.

FIG. 6 illustrates a system 600 including the transformer assembly 400 of FIGS. 4 and 5, and a housing 602 positioned about the transformer assembly 400. As shown in FIG. 6, the housing 602 includes horizontal flanges 604, 606, 608, 610. The flanges 604, 606 define an opening for receiving the circuit board 424, and the flanges 608, 610 define an opening for receiving the circuit board 426. As shown in the example of FIG. 6, each opening has a height larger than a height of the circuit boards 424, 426. This allows the circuit boards 424, 426 to move between the openings. Additionally, the flanges 604, 608 define supports for supporting the circuit boards 424, 426, respectively.

As described above, the terminal block 204 is moveable along the length of the bosses 216, 218. This provides flexibility when installing the transformer assembly 400 in the housing 602 and reduces or eliminates stress on solder joints.

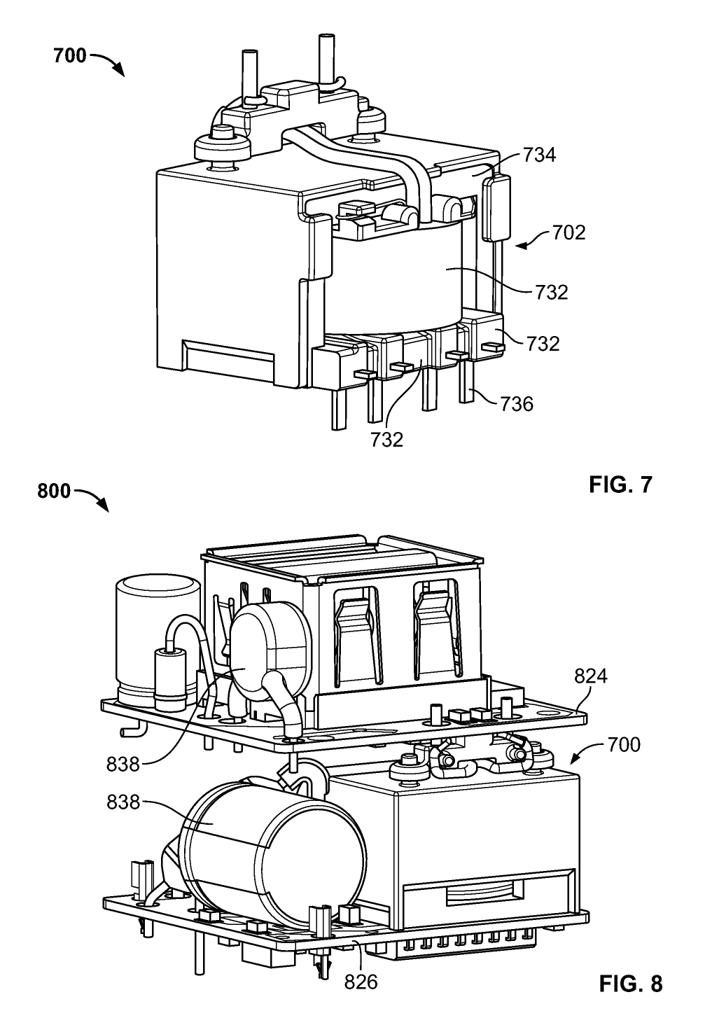

FIG. 7 illustrates a transformer assembly 700 similar to the transformer assembly 200 of FIGS. 2 and 3. The transformer assembly 700, however, includes a bobbin 732 adjacent a magnetic core 734 of a transformer 702. As shown in FIG. 7, the transformer 702 includes four terminals 736 extending through the bobbin 732. The terminals 736 may electrically couple the transformer 702 to a circuit board (e.g., the circuit board 426 of FIGS. 4 and 5).

As shown in FIG. 7, the terminals 736 are through-hole pins. Alternatively, the terminals 736 may be surface mount terminals or any other suitable terminal for coupling the transformer to a circuit board. Although four terminals 736 are shown in FIG. 7, more or less terminals may be employed.

FIG. 8 illustrates a system 800 including the transformer assembly 700 of FIG. 7 coupled to circuit boards 824, 826. The system 800 further includes components 838 coupled to the circuit boards 824, 826. The components 838 may include, for example, electrical components such as capacitors, inductors, diodes, etc. The system 800 may be, for example, a power converter, etc. and may be employed in chargers, power adapters, etc. The power converter may be, for example, a DC-DC power converter, an AC-DC power converter, a DC-AC inverter, etc.

In some embodiments, the circuit board 824 may be a secondary circuit board and include components electrically coupled to secondary winding(s) of the transformer 702. Likewise, the circuit board 826 may be a primary circuit board and include components electrically coupled to primary winding(s) of the transformer 702.

The terminal blocks and bobbins described herein may be formed of any suitable material(s). For example, the terminal blocks and bobbins may formed of a polymer such as polyamide.

The magnetic cores described herein may include any suitable magnetic material(s) including, for example, manganese zinc (MnZn) ferrites, etc. Additionally, the magnetic cores may include any suitable core configuration including, for example, E-shaped, I-shaped, U-shaped, C-shaped, toroidal, etc. Further, the magnetic cores may include one or more core sections.

The circuit boards described herein may be any suitable circuit boards including, for example, printed circuit boards. The printed circuit boards may include conductive traces for electrically connecting components, terminals, etc.

The transformer assemblies described herein may be manufactured, assembled, etc. in any suitable manner. For example, the transformer assemblies may be assembled by electrically coupling a transformer to a circuit board, electrically coupling a winding wire from the transformer to a terminal block, moveably connecting the terminal block to the transformer, and manually soldering a terminal of the terminal block to another circuit board. The transformer assemblies may be assembled in the order described immediately above or in any other suitable order. In some embodiments, electrically coupling the transformer to the circuit board includes wave soldering a terminal extending from the transformer to the circuit board.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

1. A transformer assembly comprising:
a first circuit board;
a transformer electrically coupled to the first circuit board, the transformer including a magnetic core and a winding having a winding wire extending from the winding;
a terminal block moveably connected to the transformer and moveable relative to the transformer in at least a first direction, the terminal block including a terminal, the winding wire electrically coupled to the terminal of the terminal block; and
a second circuit board electrically coupled to the terminal of the terminal block.

2. The transformer assembly of claim 1 wherein the winding is a secondary winding.

3. The transformer assembly of claim 1 wherein the winding wire is triple insulated.

4. The transformer assembly of claim 2 wherein the transformer includes a first side and a second side opposing the first side, wherein the first circuit board is coupled to the first side of the transformer and wherein the second circuit board is coupled to the terminal of the terminal block on the second side of the transformer.

5. The transformer assembly of claim 1 wherein the transformer includes a terminal electrically coupled to the first circuit board.

6. The transformer assembly of claim 5 wherein the transformer terminal is electrically coupled to the first circuit board via solder.

7. The transformer assembly of claim 1 wherein the transformer includes a bobbin adjacent the magnetic core of the transformer and a terminal extending through the bobbin, and wherein the transformer is electrically coupled to the first circuit board via the terminal extending through the bobbin.

8. The transformer assembly of claim 7 wherein the terminal extending through the bobbin is electrically coupled to the first circuit board via solder.

9. The transformer assembly of claim 1 wherein the first direction is a vertical direction.

10. The transformer assembly of claim 1 wherein the terminal block is moveable relative to the transformer in only the first direction.

11. The transformer assembly of claim 1 wherein the terminal block defines a channel and wherein the winding wire extends through the terminal block channel.

12. The transformer assembly of claim 11 wherein the winding wire is attached to the terminal block.

13. The transformer assembly of claim 1 wherein the terminal block defines an aperture and wherein the transformer includes a boss extending through the terminal block aperture.

14. The transformer assembly of claim 13 wherein the boss extends a length in the first direction and wherein the terminal block is moveable along the length of the boss.

15. A power converter comprising the transformer assembly of claim 1.

16. (canceled)
